(19) United States
(12) Patent Application Publication
(10) Pub. No.: US 2022/0392820 A1
(43) Pub. Date: Dec. 8, 2022

(54) INTEGRATED CIRCUIT OPTICAL PACKAGE

(71) Applicant: STMicroelectronics (Grenoble 2) SAS, Grenoble (FR)

(72) Inventors: Romain COFFY, Voiron (FR); Younes BOUTALEB, Grenoble (FR)

(73) Assignee: STMicroelectronics (Grenoble 2) SAS, Grenoble (FR)

(21) Appl. No.: 17/833,153

(22) Filed: Jun. 6, 2022

(30) Foreign Application Priority Data
Jun. 8, 2021 (FR) 2106000

(51) Int. Cl. H01L 23/367; H01L 33/64; H01L 31/024; H01L 33/58; H01L 31/0232; H01L 33/62; H01L 31/02; H01L 23/00

(52) U.S. Cl. CPC H01L 23/367; H01L 33/642; H01L 31/024; H01L 33/58; H01L 31/02325; H01L 33/62; H01L 31/02002; H01L 24/48; H01L 2224/48221

(57) ABSTRACT

A cap is mounted to a support substrate, the cap including a cap body and an optical shutter. The cap and support substrate define a housing. An electronic chip is disposed in the housing above the support substrate. A face of the electronic chip supports an optical device that is optically coupled with the optical shutter. The cap body is thermally conductive. Within the housing, a thermally conductive linking structure is coupled in a thermally conductive manner between the cap body and the electronic chip. The thermally conductive linking structure surrounds the electronic chip. A thermal interface material fills a portion of the housing between the thermally conductive linking structure and the cap body.

### PRIORITY CLAIM

This application claims the priority benefit of French Application for Patent No. 2106000, filed on Jun. 8, 2021, the content of which is hereby incorporated by reference in its entirety to the maximum extent allowable by law.

### TECHNICAL FIELD

Implementations and embodiments relate to the field of microelectronics, particularly the field of integrated circuit packaging, and more particularly integrated circuit optical packages having a structure enabling them to offer better heat dissipation, for example, but not limited to, packages housing chips attached according to an assembly of the “flip chip” type well known by the person skilled in the art.

### BACKGROUND

An integrated circuit optical package generally comprises an integrated circuit chip supported by a support substrate, this chip being equipped on the face opposite to that facing the support substrate, with a light emitting or light receiving optical device.

The optical package also includes an optical shutter, for example but not limited to a window, disposed optically coupled with the optical device located on the chip.

During operation, the chip and the optical device generate heat that should be dissipated. Yet, it may prove difficult to effectively dissipate this heat, in particular when the optical device is mounted on the rear face of the chip attached on the support substrate according to an assembly of the flip chip type.

Indeed, the location of the optical device on the rear face of the chip and the presence of the window allow a dissipation of heat only towards the support substrate.

Therefore, there is a need to improve the thermal dissipation of integrated circuit optical packages, in particular but not limited to those including a chip attached on the support substrate according to an assembly of the flip chip type.

### SUMMARY

According to one aspect, an integrated circuit optical package comprises a support substrate and a cap defining with the support substrate a housing. This cap includes a cap body attached on the support substrate and an optical shutter, for example but not limited to a window, attached on the cap body. The optical package also includes an electronic chip disposed in the housing above the support substrate and having a face supporting an optical device, for example a light emitting or light receiving optical device, optically coupled with the optical shutter.

The cap body is thermally conductive, for example made of copper, and the package further comprises in said housing a thermally conductive linking structure coupled in a thermally conductive manner between the cap body and the electronic chip.

This thermally conductive linking structure thus forms with the cap body, which is itself thermally conductive, an additional path for dissipating heat, which improves the overall thermal dissipation of the package.

It is thus possible to significantly reduce the thermal resistance of the package, for example in the order of 60%.

The thermally conductive linking structure may be for example made of copper.

The thermally conductive linking structure may have any shape.

The thermally conductive linking structure may only include a single pillar.

However, the thermally conductive linking structure may advantageously form a ring surrounding the optical device.

A ring increases the size of the additional thermal dissipation path.

Although it is possible to produce a continuous ring, it is preferable that the ring is discontinuous so as to limit the mechanical stresses between the ring and the face of the chip supporting the optical device.

Indeed, this face, when it is the rear face of the chip, may be made of silicon. In addition, the thermal expansion coefficients between the material of the ring and the material of the chip are generally different and cause these thermal stresses which, as indicated above, are advantageously reduced when the ring is discontinuous.

The discontinuous ring may comprise a plurality of conductive elements, for example pillars having a circular or oblong base or even of elongated shape, for example made of copper, protruding from said face of the chip and attached on the cap body by a thermally conductive attachment, for example by solder pads made of tin and/or silver.

According to one alternative embodiment, the chip may be disposed above the substrate according to an assembly of the flip chip type and said face of the chip supporting the optical device is then a rear face of the chip.

According to another possible alternative embodiment, said face of the chip supporting the optical device may be a front face of the chip, the chip is then disposed above the substrate by means of a rear face, opposite the front face and electrical connection wires connect the front face of the chip to the support substrate.

According to one embodiment, said thermally conductive linking structure defines a first portion of said housing containing the optical device and a second portion of said housing located between the thermally conductive linking structure and the cap body.

So as to further improve the thermal dissipation of the package, it is particularly advantageous that the package further comprises a thermal interface material (TIM), this thermal interface material filling the second portion of the housing.

According to another aspect, a method for manufacturing an integrated circuit optical package, comprises: providing an electronic chip having a face supporting an optical device; producing, in a housing defined by a support substrate and a cap including a thermally conductive cap body attached on the support substrate and an optical shutter attached on the cap body, a thermally conductive linking structure, and thermally conductively coupling the thermally conductive linking structure between the cap body and the electronic chip disposed in the housing above the support substrate, the optical device being optically coupled with the optical shutter.

According to one implementation, producing the thermally conductive linking structure comprises producing a ring surrounding the chip.

According to one implementation, producing the ring comprises producing a discontinuous ring.

According to one implementation, producing the ring comprises producing a plurality of thermally conductive elements protruding from said face of the chip and thermally conductively coupling the thermally conductive linking structure comprising attaching these protruding elements on the cap body by a thermally conductive attachment.

According to one variant, the method comprises attaching the chip on the support substrate by an assembly of the flip chip type, said face of the chip being a rear face.

According to one embodiment compatible with this variant, the method comprises, prior to producing the thermally conductive linking structure, producing electrically conductive connections on a front face of the chip, for example beads; and after producing the thermally conductive linking structure, attaching the chip on the support substrate by way of said electrically conductive connections; and covering the electrically conductive connections with an underfill; attaching the cap body on the support substrate; and thermally conductive coupling the thermally conductive linking structure with the cap body.

According to another variant, the method comprises attaching the chip on the substrate by a rear face of the chip, opposite said face supporting the optical device that is a front face.

According to one embodiment compatible with this other variant, the method comprises after producing the thermally conductive linking structure, attaching the chip on the support substrate, forming electrical connection wires between the front face of the chip and the support substrate, attaching the cap body on the support substrate and thermally conductive coupling of the thermally conductive linking structure with the cap body.

According to one embodiment, producing the thermally conductive linking structure defines a first portion of said housing containing the optical device and a second portion of said housing located between the thermally conductive linking structure and the cap body, and the method further comprises filling the second portion of the housing with a thermal interface material.

### BRIEF DESCRIPTION OF THE DRAWINGS

Other advantages and features of the invention will become apparent upon examination of the detailed description of non-limiting implementations and embodiments, and of the appended drawings, wherein:

FIG. 1 is a cross sectional view of an integrated circuit optical package;

FIG. 2 is a top view that illustrates an outline of protruding elements;

FIG. 3 is a cross sectional view of an integrated circuit optical package;

FIG. 4 is a cross sectional view of an integrated circuit optical package;

FIG. 5 is a flow diagram illustrating a method for manufacturing an optical package of the type illustrated in FIG. 1; and

FIG. 6 is a flow diagram illustrating a method for manufacturing an optical package of the type illustrated in FIG. 3.

### DETAILED DESCRIPTION

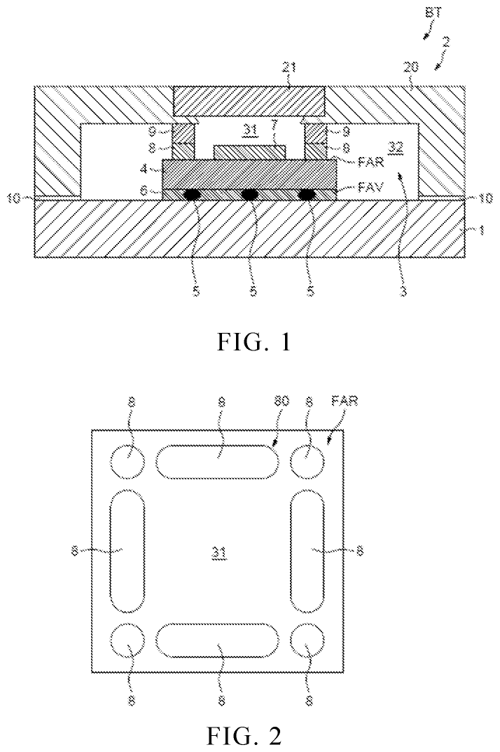

In FIG. 1, the reference BT designates an integrated circuit optical package.

This package BT includes a support substrate 1 of structure that is conventional and known per se, as well as a cap 2 defining, with the support substrate, a housing 3.

The cap 2 includes here a cap body 20, made of a thermally conductive material, for example made of copper, attached on the support substrate here by a bead of glue 10.

The cap 2 also includes an optical shutter 21 attached on the cap body 20.

This optical shutter may be a window able to be optically transparent or filtering or have miscellaneous features such as the polarization for example, but not exclusively.

It is also possible that the optical shutter 21 comprises a lens.

The package BT also includes an electronic integrated circuit chip 4 disposed in the housing 3 above the support substrate 1. In the example of embodiment of FIG. 1, the chip 4 is attached on the support substrate according to an assembly of the flip chip type.

In other words, the front face FAV of the chip is electrically connected on metal tracks of the support substrate by electrical connection means 5, such as for example solder beads or balls embedded in an underfill 6 as known by the person skilled in the art.

The underfill 6 is intended to fill the voids existing between the connection balls 5. This underfill is electrically insulating and makes it possible to avoid possible short circuits. It also makes it possible to absorb a portion of the mechanical stresses.

The rear face FAR of the chip, opposite the front face FAV, supports an optical device 7 that is optically coupled with the optical shutter means 21.

The optical device 7 may be, in this example, a light emitting device, for example a laser diode network.

The optical package BT also includes in the housing 3 a thermally conductive linking structure 8 coupled in a thermally conductive manner between the cap body 20 and the electronic chip 4.

In this example, the thermally conductive linking structure includes a plurality of thermally conductive elements, for example made of copper, 8, protruding from the rear face FAR of the chip and integral with the cap body 20 by, for example solder pads 9 made of tin and/or silver.

As shown in FIG. 2 which illustrates the outline of the protruding elements 8, for example pillars, on the rear face FAR of the chip, it can be seen that these protruding elements form a discontinuous ring 80, delimiting a first portion 31 of the housing 3 wherein is located the optical device 7.

The ring 80 therefore surrounds this optical device.

The ring 80 also defines a second portion 32 of the housing located between the ring and the cap body 20.

In the example of embodiment of FIG. 1, this second portion 32 of the housing is empty.

The copper pillars 8 are, for example, directly in contact with the silicon of the chip 4. These pillars 8, as well as the solder pads 9 and the cap body 20 form a heat dissipation path making it possible to improve the thermal dissipation of the package.

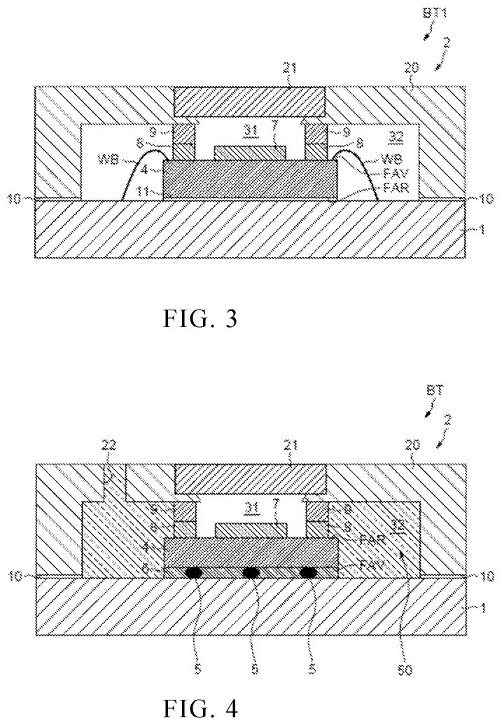

It will be noted that the embodiment herein is not limited to an assembly of the chip of the flip chip type, as schematically illustrated in FIG. 1, but may also apply to an assembly of the chip by means of its rear face as schematically illustrated in FIG. 3.

Only the differences between FIG. 2 and FIG. 3 will now be described.

In the package BT1 of FIG. 3, the pillars 8 protrude this time from the front face FAV of the chip and the contact pads located on the front face of the chip FAV are electrically connected on metal tracks of the support substrate by means of the electrically conductive linking wire WB.

The assembly of the chip is therefore here an assembly of the wire bonding type.

The rear face FAR of the chip is attached on the support substrate 1 by means for example of a conventional glue layer 11.

The optical device 7 may be a light emitting device or a light receiving device.

The wires WB are located outside of the pillars 8.

So as to further improve the thermal dissipation of the package, it is provided, as illustrated in FIG. 4 on which is found an assembly of the chip of the flip chip type, to fill the second portion 32 of the housing with a thermal interface material (TIM) 50 by means of a hole 22 arranged in the cap body 20.

The thermal interface materials are indeed known to the person skilled in the art. By way of non-limiting example, it is possible for example to use the material from the company DOW known under the name DOWSIL DA-6534 that is a material having a significant thermal conductivity, typically 6.8 Watts per meter and per degree Kelvin.

Of course, filling the second portion 32 of the housing is also compatible with an assembly of the wire bonding type of the chip such as illustrated in FIG. 3.

In the case where the thermally conductive linking structure 8 has the form of a discontinuous ring, as illustrated for example in FIG. 2, a spacing will be selected between the various pillars of the ring that is small enough to prevent introduction of the thermal interface material into the first portion 31 of the housing containing the optical device 7, during the phase of filling the second portion 32 of the housing with this thermal interface material.

As an indication, a spacing of between 10 micrometers and 30 micrometers may be selected.

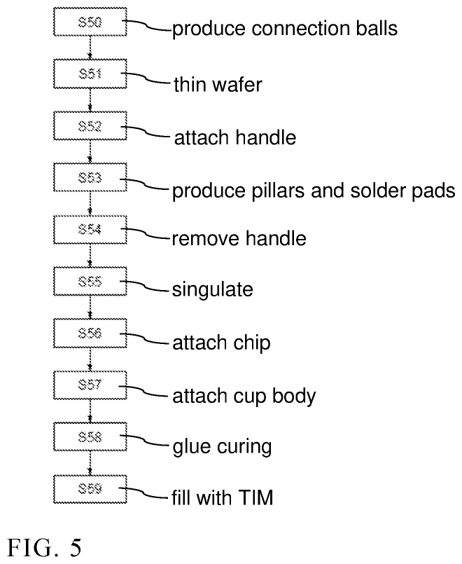

Reference will now be made more particularly to FIG. 5 to describe an implementation of a method for manufacturing an optical package of the type illustrated in FIG. 1.

In step S50, on the front faces of all of the chips produced on a semiconductor wafer, the connection balls 5 are produced in a conventional manner and known per se. As an indication, it may be possible to use a similar method to that which will be described subsequently in step S53.

Generally, the thickness of the semiconductor wafer is relatively thick. In addition, when it is necessary for certain applications, to reduce this thickness, a reduction of thickness of the semiconductor wafer is carried out in step S51, in a conventional manner and known per se.

Then, in step S52, on the front faces equipped with bump contacts of all of the chips of the wafer, a support used as a handle is attached, with the aid for example of a film or a thermally degradable glue.

Of course, steps S51 and S52 may be inverted.

In step S53, the production of the copper pillars 8 is carried out topped by their solder pads.

More specifically, on the rear face of the entire wafer an electrolytic seed layer is formed.

Then, above this seed layer, a photosensitive resin layer is deposited.

Then, through conventional steps of photolithography, resin insulation and revelation, recesses are formed in the photosensitive resin recesses defining the places for the future copper pillars.

Subsequently, the wafer is plunged into a copper bath so as to increase the copper by plating in the recesses of the resin.

Subsequently, a bath of tin and/or silver is used so as to form the solder pads that top the copper pillars.

Then, the photosensitive resin is removed and the portion of the seed layer located outside of the copper pillars is etched so as to for example reveal the silicon of the wafer.

Then, in step S54, the handle support is removed with the aid of heat treatment or by laser then, in step S55, the sawing of the wafer is carried out so as to individualize (i.e., singulate) the electronic chips provided on their front face with connection balls 5 and on their rear face with copper pillars 8 topped with solder pads.

Subsequently, in step S56 the soldering of the electronic chip on the support substrate in an oven then the delivery of the underfill 6 is carried out, in a conventional manner and known per se.

In step S57, the cap body is attached on the package with the aid of a bead of glue.

In this regard, heat treatment can be performed, for example at 260° C., so as to perform this attachment of the cap on the substrate and simultaneously melt the solder pads so as to secure the copper pillars 8 with the cap body 20.

Subsequently, a step S58 of hardening the glue located between the cap body and the substrate (glue curing) is carried out.

Then, optionally, it is possible, in step S59, to carry out the filling of the second portion 32 of the housing with the thermal interface material after having drilled the cap body 20.

Alternatively, the cap body may be drilled during its manufacture.

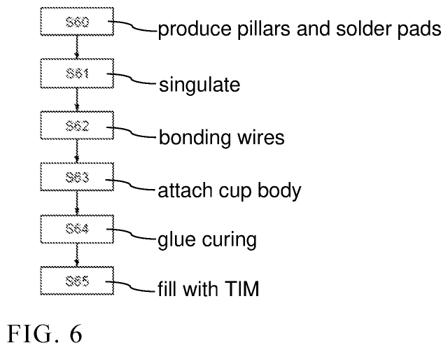

Reference will now be made more particularly to FIG. 6 to describe an implementation of the manufacturing method making it possible to obtain a package BT1 similar to that illustrated in FIG. 3.

This time, in step S60, on the front face of all of the chips of the wafer, the copper pillars 8 topped with solder pads are produced in a similar way to that described in step S53.

Then, in S61 the cutting of the semiconductor wafer is carried out so as to individualise the chips.

In step S62, outside of the copper pillars, the soldering of the electrically conductive linking wires is performed connecting the contact pads of the front face of the chip with metal ranges of the support substrate (wire bonding).

Then, in step S63, the attachment of the cap on the substrate is carried out in a similar way to that described above.

In step S64, the treatment for hardening the glue is carried out and optionally, the second portion 32 of the housing is filled with the thermal interface material in step S65.

1. An integrated circuit package, comprising:
a support substrate;
a cap including a cap body attached on the support substrate and an optical shutter attached on the cap body;
wherein the cap body is thermally conductive;
wherein the cap with the support substrate defines a housing;
an electronic chip disposed within the housing in a position above the support substrate, said electronic chip having a face supporting an optical device that is optically coupled with the optical shutter; and
a thermally conductive linking structure located within said housing, said thermally conductive linking structure having a first end coupled in a thermally conductive manner to the cap body and having a second end coupled in a thermally conductive manner to the face of the electronic chip.

2. The package according to claim 1, wherein the thermally conductive linking structure forms a ring surrounding the optical device.

3. The package according to claim 2, wherein the ring is discontinuous.

4. The package according to claim 1, wherein the thermally conductive linking structure comprises a plurality of thermally conductive elements protruding from said face of the chip and connected to an underside of the cap body by a thermally conductive attachment.

5. The package according to claim 4, wherein the electronic chip is disposed above the support substrate according to an assembly of a flip chip type and said face of the electronic chip is a rear face of the electronic chip.

6. The package according to claim 4, wherein said face of the electronic chip is a front face of the electronic chip, wherein a rear face of the electronic chip is disposed over the support substrate and further comprising electrical connection wires configured to connect the front face of the electronic chip to the support substrate.

7. The package according to claim 1, wherein said thermally conductive linking structure surrounds a first portion of said housing containing the optical device and wherein a second portion of said housing is located between the thermally conductive linking structure and the cap body, and further comprising a thermal interface material filling the second portion of the housing.

8. An integrated circuit package, comprising:
a support substrate;
a cap including a cap body attached on the support substrate;
wherein the cap body is thermally conductive;
wherein the cap with the support substrate defines a housing;
an electronic chip disposed within the housing in a position above the support substrate, said electronic chip having a face; and
a thermally conductive linking structure located within said housing, said thermally conductive linking structure having a first end thermally coupled to an underside of the cap body and having a second end thermally coupled to the face of the electronic chip.

9. The package according to claim 8, wherein the thermally conductive linking structure is shaped in the form of a ring.

10. The package according to claim 9, wherein said ring for the thermally conductive linking structure surrounds an optical device of the electronic chip.

11. The package according to claim 9, wherein the ring is discontinuous.

12. The package according to claim 8, wherein the thermally conductive linking structure comprises a plurality of thermally conductive elements, wherein each thermally conductive element comprises a first end thermally coupled to the underside of the cap body and a second end thermally coupled to the face of the electronic chip.

13. The package according to claim 8, wherein the electronic chip is disposed above the support substrate according to an assembly of a flip chip type and said face of the electronic chip is a rear face of the electronic chip.

14. The package according to claim 8, wherein said face of the electronic chip is a front face of the electronic chip, wherein a rear face of the electronic chip is disposed over the support substrate and further comprising electrical connection wires configured to connect the front face of the electronic chip to the support substrate.

15. The package according to claim 8, wherein said thermally conductive linking structure surrounds a first portion of said housing, wherein a second portion of said housing is located between the thermally conductive linking structure and the cap body, and further comprising a thermal interface material filling the second portion of the housing.

16. A method for manufacturing an integrated circuit optical package, comprising:
providing an electronic chip having a face supporting an optical device;
producing a thermally conductive linking structure in a housing defined by a support substrate and a cap, wherein the cap includes a thermally conductive cap body attached on the support substrate and an optical shutter attached on the thermally conductive cap body;
wherein the optical device is optically coupled with the optical shutter; and
thermally conductive coupling a first end of the thermally conductive linking structure to the cap body and thermally conductive coupling a second end of the thermally conductive linking structure to the electronic chip disposed in the housing.

17. The method according to claim 16, wherein producing the thermally conductive linking structure comprises producing the thermally conductive linking structure as a ring surrounding the optical device.

18. The method according to claim 17, wherein the ring is a discontinuous ring.

19. The method according to claim 17, wherein producing the thermally conductive linking structure comprises producing a plurality of thermally conductive elements protruding from said face of the electronic chip; and
wherein thermally conductively coupling the thermally conductive linking structure comprises attaching a first end of each thermally conductive element to said face of the electronic chip and attaching a second end of each thermally conductive element to the cap body.

20. The method according to claim 16, further comprising attaching the electronic chip on the support substrate by an assembly of a flip chip type, wherein said face of the electronic chip is a rear face.

21. The method according to claim 20, further comprising,
prior to producing the thermally conductive linking structure, producing an electrically conductive connection on a front face of the chip; and
after producing the thermally conductive linking structure:
attaching the electronic chip on the support substrate using said electrically conductive a connection and covering the electrically conductive connection with an underfill; and
attaching the cap body on the support substrate; and
wherein thermally conductively coupling comprises coupling the thermally conductive linking structure with the cap body.

22. The method according to claim 16, further comprising attaching the electronic chip on the support substrate by a rear face of the electronic chip, wherein said face supporting the optical device is a front face of the electronic chip.

23. The method according to claim 22, further comprising, after producing the thermally conductive linking structure:
forming electrical connection wires between the front face of the electronic chip and the support substrate;
attaching the cap body on the support substrate; and
thermally conductively coupling the thermally conductive linking structure with the cap body.

24. The method according to claim 16, wherein the thermally conductive linking structure surrounds a first portion of said housing containing the electronic chip, wherein a second portion of said housing is located between the thermally conductive linking structure and the cap body, and further comprising filling the second portion of the housing with a thermal interface material.
